(19) United States
(12) Patent Application Publication
(10) Pub. No.: US 2025/0331355 A1
(43) Pub. Date: Oct. 23, 2025

(54) MICRO LIGHT EMITTING CHIP, MICRO LIGHT EMITTING CHIP STRUCTURE AND DISPLAY PANEL

(71) Applicant: PlayNitride Display Co., Ltd., MiaoLi County (TW)

(72) Inventors: Ching-Liang Lin, MiaoLi County (TW); Yi-Ru Huang, MiaoLi County (TW); Chi-Hao Cheng, MiaoLi County (TW)

(73) Assignee: PlayNitride Display Co., Ltd., MiaoLi County (TW)

(21) Appl. No.: 19/186,633

(22) Filed: Apr. 23, 2025

Related U.S. Application Data
(60) Provisional application No. 63/637,676, filed on Apr. 23, 2024.

(51) Int. Cl. H10H 29/85; H01L 25/075; H10H 29/80

(52) U.S. Cl. CPC H10H 29/857; H01L 25/0753; H10H 29/8321

(57) ABSTRACT

Provided is a micro light emitting chip, which includes two sub-chips, an insulating structure, a first electrode, a second electrode, and a conductive element. The insulating structure is disposed between the two sub-chips to allow the two sub-chips to be electrically insulated from each other at the insulating structure. The first electrode and the second electrode are respectively connected to the two sub-chips and respectively have a first notch and a second notch. The conductive element is disposed between the first notch of the first electrode and the second notch of the second electrode, and electrically connected to the two sub-chips. A sum of orthogonal projection areas of the first electrode, the second electrode and the conductive element on a reference plane parallel to the two sub-chips is greater than or equal to 0.6 times an orthogonal projection area of the micro light emitting chip on the reference plane. Also provided are a micro light emitting chip structure and a display panel.

### CROSS-REFERENCE TO RELATED APPLICATION

This application claims the priority benefit of U.S. provisional application Ser. No. 63/637,676, filed on Apr. 23, 2024. The entirety of the above-mentioned patent application is hereby incorporated by reference herein and made a part of this specification.

### BACKGROUND

### Technical Field

The disclosure relates to a light emitting element and a structure and a panel which include the same, and particularly relates to a micro light emitting chip, a micro light emitting chip structure and a display panel.

### Related Art

A micro light emitting diode panel includes an active element substrate and micro light-emitting diodes (micro-LEDs) on the active element substrate, and is electrically connected to a driving circuit layer in the active element substrate. The micro light emitting diode panel has become the focus of research and development by major manufacturers due to advantages such as high brightness, high resolution, and high contrast.

In conventional tandem chip structures, general electrode have no notch, thus an area of a conductive layer configured to serially connect two chips is limited, being more difficult to support the strength of an overall chip structure that is serially connected, so that the overall chip structure is easier to break at a junction where the two serially connected chips are bonded during mass transfer to a circuit substrate, resulting in a decrease in a yield rate of the display panel.

### SUMMARY

The disclosure provides a micro light emitting chip, which has better structural strength.

The disclosure provides a micro light emitting chip structure, which has better structural strength and manufacturing yield rate.

The disclosure provides a display panel, which has better structural strength and manufacturing yield rate.

An embodiment of the disclosure proposes a micro light emitting chip, which includes two sub-chips, an insulating structure, a first electrode, a second electrode, and a conductive element. The insulating structure is disposed between the two sub-chips to allow the two sub-chips to be electrically insulated from each other at the insulating structure. The first electrode and the second electrode are respectively connected to the two sub-chips, and respectively have a first notch and a second notch. The conductive element is configured between the first notch of the first electrode and the second notch of the second electrode, and electrically connected to the two sub-chips. A sum of orthogonal projection areas of the first electrode, the second electrode, and the conductive element on a reference plane parallel to the two sub-chips is greater than or equal to 0.6 times an orthogonal projection area of the micro light emitting chip on the reference plane.

An embodiment of the disclosure proposes a micro light emitting chip structure, which includes a temporary substrate, a fixing element, and the multiple foregoing micro light emitting chips. The micro light emitting chips are fixed on the temporary substrate through the fixing element. The micro light emitting chips are electrically insulated from the temporary substrate.

An embodiment of the disclosure proposes a display panel, which includes a circuit substrate and the multiple foregoing micro light emitting chips. The circuit substrate is provided with multiple pixel circuits. The micro light emitting chips are disposed on the circuit substrate. One of the first electrode and the second electrode is electrically bonded to one of the pixel circuits.

An embodiment of the disclosure proposes a micro light emitting chip, which includes two sub-chips, an insulating structure, a first electrode, a second electrode, and a conductive element. The insulating structure is disposed between the two sub-chips to allow the two sub-chips to be electrically insulated from each other at the insulating structure. The first electrode and the second electrode are respectively connected to the two sub-chips, and respectively have a first notch and a second notch. The conductive element is configured between the first notch of the first electrode and the second notch of the second electrode, and electrically connected to the two sub-chips. The first notch and the second notch are away from each other, and an outer profile of the first electrode and an outer profile of the second electrode are in 180-degree rotational symmetry.

In the micro light emitting chip, the micro light emitting chip structure, and the display panel of the embodiment of the disclosure, the first electrode and the second electrode respectively have the first notch and the second notch. The conductive element is configured between the first notch of the first electrode and the second notch of the second electrode. The sum of the orthogonal projection areas of the first electrode, the second electrode and the conductive element on the reference plane parallel to the two sub-chips is greater than or equal to 0.6 times the orthogonal projection area of the micro light emitting chip on the reference plane. Alternatively, the first notch and the second notch are away from each other, and the outer profile of the first electrode and the outer profile of the second electrode are in 180-degree rotational symmetry. Therefore, the conductive element may have a larger area, and may support the structural strength of the connected two sub-chips to effectively reduce breakage or tilting of the micro light emitting chip at a connection point of the two sub-chips due to uneven force during a mass transfer process. Thus, the micro light emitting chip of the embodiment of the disclosure can have better structural strength. The micro light emitting chip structure and the display panel of the embodiment of the disclosure can have better structural strength and manufacturing yield rate.

### BRIEF DESCRIPTION OF THE DRAWINGS

FIG. 1A is a schematic cross-sectional view of a micro light emitting chip according to an embodiment of the disclosure.

FIG. 1B is a schematic bottom view of the micro light emitting chip in FIG. 1A.

FIG. 2 is a schematic cross-sectional view of a micro light emitting chip according to an embodiment of the disclosure.

FIG. 3 is a schematic cross-sectional view of a micro light emitting chip structure according to an embodiment of the disclosure.

FIG. 4 is a schematic cross-sectional view of a display panel according to an embodiment of the disclosure.

FIG. 5 is a schematic bottom view of a micro light emitting chip according to another embodiment of the disclosure.

FIG. 6 is a schematic bottom view of a micro light emitting chip according to yet another embodiment of the disclosure.

### DESCRIPTION OF THE EMBODIMENTS

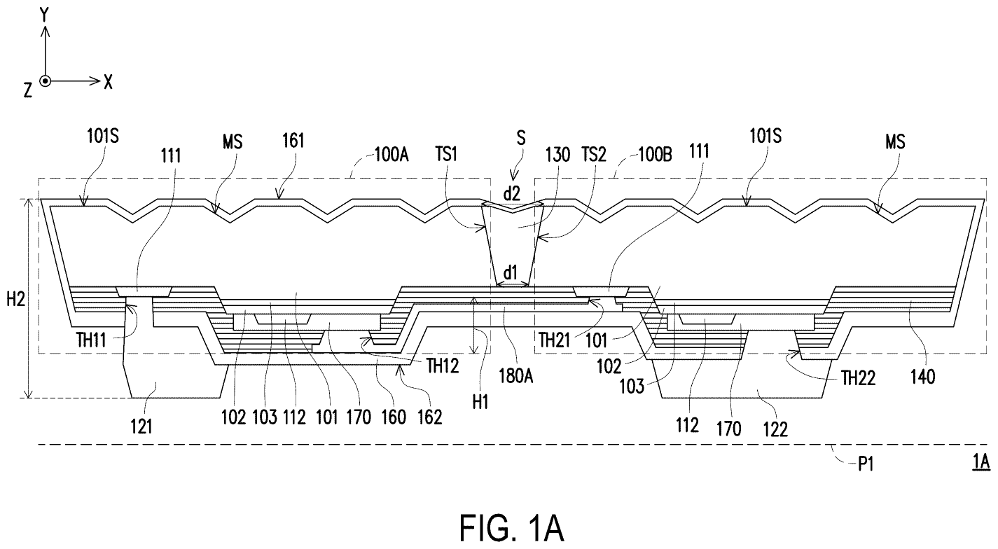

FIG. 1A is a schematic cross-sectional view of a micro light emitting chip according to an embodiment of the disclosure, and FIG. 1B is a schematic bottom view of the micro light emitting chip in FIG. 1A. FIG. 1A is a schematic cross-sectional view of the micro light emitting chip in FIG. 1B along line I-I. Referring to FIG. 1A and FIG. 1B, a micro light emitting chip 1A of the embodiment includes two sub-chips (such as a first sub-chip 100A and a second sub-chip 100B), a first electrode 121, a second electrode 122, an insulating structure 130, a conductive element 180A, and a protective unit 160. The first sub-chip 100A and the second sub-chip 100B are, for example, micro light emitting diodes (micro LEDs), micro laser diodes, or light emitting diodes of other sizes, and the disclosure is not limited thereto. Preferably, the embodiment uses micro light emitting diodes.

On the other hand, the light emitted by the first sub-chip 100A and the second sub-chip 100B may have substantially a same wavelength range. For example, the first sub-chip 100A and the second sub-chip 100B may both be red micro light emitting diodes, green micro light emitting diodes, or blue micro light emitting diodes. On the other hand, the micro light emitting chip 1A of the embodiment is a flip-chip type micro light emitting diode. For example, through the first electrode 121 and the second electrode 122 located on a same side of an epitaxial structure of the micro light emitting chip 1A, the micro light emitting chip 1A is aligned with corresponding bonding pads on a pixel circuit (to be described later), and are bonded with each other after mass transfer to achieve electrical connection between the micro light emitting chip 1A and the pixel circuit, but the disclosure is not limited thereto.

The first sub-chip 100A and the second sub-chip 100B may each include a first semiconductor layer 101, a second semiconductor layer 102, and a light emitting layer 103 sequentially epitaxially grown in a direction Y. The first semiconductor layer 101 may be composed of a III-V group or II-VI group compound semiconductor, and may be a P-type or N-type doped semiconductor material layer. The second semiconductor layer 102 is formed on the light emitting layer 103, and may be composed of a III-V group or II-VI group compound semiconductor, and may be a P-type or N-type doped semiconductor material layer. One of the first semiconductor layer 101 and the second semiconductor layer 102 is an N-type semiconductor layer, and another one of the first semiconductor layer 101 and the second semiconductor layer is a P-type semiconductor layer.

The first electrode 121 and the second electrode 122 may be aluminum (Al), gold (Au), silver (Ag), copper (Cu), germanium gold (GeAu) or other metals or alloys that are appropriate to generate ohmic contact with a P-type semiconductor and a N-type semiconductor, and materials that are appropriate to generate connection with a metal bonding pad (to be described later) and a welding metal of the pixel circuit, but the disclosure is not limited thereto.

The first electrode 121 may be electrically connected to the first semiconductor layer 101 of the first sub-chip 100A through a via TH11. The second electrode 122 may be electrically connected to the second semiconductor layer 102 of the second sub-chip 100B through a via TH22. In addition, the conductive element 180A may be further electrically connected to the first sub-chip 100A and the second sub-chip 100B, so that the first sub-chip 100A and the second sub-chip 100B are serially connected. For example, the conductive element 180A may be extended in a direction X and disposed on a same side of the first sub-chip 100A and the second sub-chip 100B. Two ends of the conductive element 180A may be respectively electrically connected to the second semiconductor layer 102 of the first sub-chip 100A and the first semiconductor layer 101 of the second sub-chip 100B. The conductive element 180A may be a metal material, such as copper, silver, molybdenum, titanium or alloys thereof; may also be a transparent conductive material, such as indium tin oxide (ITO) or indium gallium zinc oxide (ITZO), and the disclosure is not limited thereto.

Accordingly, when the micro light emitting chip 1A is enabled, the first electrode 121 may be selectively provided with a high potential, and the second electrode 122 may be selectively provided with a low potential or a ground potential. Due to the potential difference generated between the first electrode 121 and the second electrode 122, current may flow from the first electrode 121, sequentially through the first semiconductor layer 101, the light emitting layer 103, and the second semiconductor layer 102 of the first sub-chip 100A to the conductive element 180A, and then transmit to the first semiconductor layer 101, the light emitting layer 103, and the second semiconductor layer 102 of the second sub-chip 100B and the second electrode 122 to allow both the first sub-chip 100A and the second sub-chip 100B to emit light.

By means of the above, the serial connection structure of the micro light emitting chip 1A makes it easy to adjust a quantity of each sub-chip to adjust a partial pressure of each sub-chip, so that each sub-chip may be adapted to being provided a corresponding working voltage (for example, a working voltage of a red microLED is between 1.6 volt and 2.0 volt, and a working voltage of a blue microLED is between 3.0 volt and 3.4 volt). When the micro light emitting chip 1A is applied to different displays, a same voltage may be provided to the micro light emitting chip 1A of different color lights to achieve the function of reducing power consumption and simplifying circuits. On the other hand, the micro light emitting chip 1A may also have advantages such as high brightness, high power, and high extraction rate.

It is worth mentioning that the insulating structure 130 is disposed between the first sub-chip 100A and the second sub-chip 100B, and allows the first sub-chip 100A and the second sub-chip 100B to be electrically insulated from each other at the insulating structure 130. For example, the insulating structure 130 may be directly manufactured on the structure of the micro light emitting chip 1A, that is, the insulating structure 130 may be a portion of the micro light emitting chip 1A, and is located in a region between the first sub-chip 100A and the second sub-chip 100B (such as a space S). Here, the insulating structure 130 may utilize, for example, an ion implantation technology to change the characteristics of the first semiconductor layer 101 to allow to lose the conductivity of a semiconductor. In detail, ions may be injected to allow defects or irregularities to appear in a lattice of the first semiconductor layer 101 to trap or block carriers from passing through the insulating structure 130, thereby reducing the conductivity in the region. In addition, mechanical stress may also be applied to change the band structure to reduce the semiconductor characteristics of the insulating structure 130. The foregoing methods may be used individually or in combination. However, the disclosure is not limited thereto. In some embodiments, a material of the insulating structure 130 may be different from a material of the first semiconductor layer 101. The insulating structure 130 may be connected between the first semiconductor layer 101 of the first sub-chip 100A and the second sub-chip 100B, and respectively have a first contact surface TS1 and a second contact surface TS2. That is to say, a portion of the two sub-chips respectively adjacent to the insulating structure 130 is a semiconductor with single electrical property (for example, the first contact surface TS1 contacts the first semiconductor layer 101 of the first sub-chip 100A without contacting the second semiconductor layer 102 of the first sub-chip 100A). In the embodiment, the portion of the two sub-chips respectively adjacent to the insulating structure 130 has a same electrical property (for example, both are N-type semiconductors or both are P-type semiconductors). In addition, a space between the first contact surface TS1 and the second contact surface TS2 may define the space S, and the insulating structure 130 fills a portion of the space S. The insulating structure 130 may, for example, be an inorganic insulating material or an organic insulating material, and the disclosure is not limited thereto. In other unillustrated embodiments, the insulating structure 130 may also completely fill the space S; that is to say, the insulating structure 130 may completely cover the first contact surface TS1, the second contact surface TS2, and be flush with an upper surface 101S of the first semiconductor layer 101.

In addition, in some embodiments, the first sub-chip 100A and the second sub-chip 100B may both include a passivation layer (such as a silicon oxide layer), located on a contact surface connected to the insulating structure 130. That is to say, the first contact surface TS1 and the second contact surface TS2 may refer to portions where the passivation layer of each of the first sub-chip 100A and the second sub-chip 100B contacts the insulating structure 130.

The first electrode 121 and the second electrode 122 respectively have a first notch C1 and a second notch C2, as shown in FIG. 1B. The conductive element 180A is configured between the first notch C1 of the first electrode 121 and the second notch C2 of the second electrode 122, and electrically connected to the two sub-chips (that is, the first sub-chip 100A and the second sub-chip 100B).

Through the insulating structure 130 disposed between the first sub-chip 100A and the second sub-chip 100B in a connection direction (such as the direction X in the figure), sufficient structural strength may be provided to the micro light emitting chip 1A, and further allow the conductive element 180A to be stably connected to the first sub-chip 100A and the second sub-chip 100B, enhancing the product reliability of the micro light emitting chip 1A. In addition, by the structure where the conductive element 180A is serially connected to the sub-chips, the precision or uniformity requirements for the micro light emitting chip 1A during adhering, pickup, and transferring to other substrates may be reduced, and also less likely to be damaged, broken or tilted due to the effect of uniformity (such as flatness), effectively enhancing the transfer yield rate of the carrier mounted with the micro light emitting chip 1A, and the device reliability of the display panel provided with the micro light emitting chip 1A may also be enhanced. In the embodiment, by designing the first notch C1 and the second notch C2 in the first electrode 121 and the second electrode 122, the conductive element 180A may be allowed to extend into the notches and have a larger area, thereby further supporting the structural strength of the connected two sub-chips. In the embodiment, a sum of orthogonal projection areas of the first electrode 121, the second electrode 122 and the conductive element 180A on a reference plane P1 parallel to the two sub-chips (that is, the first sub-chip 100A and the second sub-chip 100B) is greater than or equal to 0.6 times an orthogonal projection area of the micro light emitting chip 1A on the reference plane P1. This may further ensure that the conductive element 180A has a large area to provide good structural support for the connected two sub-chips.

In the embodiment, the orthogonal projection area of the conductive element 180A on the reference plane P1 is greater than or equal to 0.1 times the orthogonal projection area of the micro light emitting chip 1A on the reference plane P1, and less than or equal to 0.5 times the orthogonal projection area of the micro light emitting chip 1A on the reference plane P1. This design may ensure that the conductive element 180A has a sufficiently large area to provide good structural support for the connected two sub-chips, and the conductive element 180A may serve as a reflection layer.

In the embodiment, the orthogonal projection area of the conductive element 180A on the reference plane P1 is greater than or equal to the orthogonal projection area of the first electrode 121 on the reference plane P1, or greater than or equal to the orthogonal projection area of the second electrode 122 on the reference plane P1.

In the embodiment, a height H1 of the conductive element 180A in a direction perpendicular to the reference plane P1 is less than a height H2 of the micro light emitting chip 1A in the direction perpendicular to the reference plane P1. In an embodiment, the height H1 may fall within a range of 0.5 micrometers to 2 micrometers. In the embodiment, the orthogonal projection of the conductive element 180A on the reference plane P1 is away from the orthogonal projection of the first electrode 121 on the reference plane P1, and away from the orthogonal projection of the second electrode 122 on the reference plane P1. This point can be seen from the bottom view of the micro light emitting chip 1A in FIG. 1B. That is to say, there is a gap G1 between the orthogonal projection of the conductive element 180A on the reference plane P1 and the orthogonal projection of the first electrode 121 on the reference plane P1, and there is a gap G2 between the orthogonal projection of the conductive element 180A on the reference plane P1 and the orthogonal projection of the second electrode 122 on the reference plane P1. In an embodiment, a minimum value of the gap G1 and the gap G2, for example, falls within a range of 0.5 micrometers to 2 micrometers.

In the embodiment, the first notch C1 and the second notch C2 are opposite to each other. In addition, in the embodiment, a ratio of a width W1 of the first notch C1 to a width W2 of the first electrode 121 is greater than or equal to 0.2 and less than or equal to 0.5, and a ratio of the width W3 of the second notch C2 to a width W4 of the second electrode 122 is greater than or equal to 0.2 and less than or equal to 0.5. That is, a ratio of a maximum width of the first notch C1 to a maximum width of the first electrode 121 in a same direction (such as the X direction) is greater than or equal to 0.2 and less than or equal to 0.5, and a ratio of a maximum width of the second notch C2 to a maximum width of the second electrode 122 in a same direction (such as the X direction) is greater than or equal to 0.2 and less than or equal to 0.5. In addition, the first notch C1 and the second notch C2 may be arc-shaped notches or polygonal notches (such as square notches), and the disclosure is not limited thereto. Moreover, a shape of a side of the conductive element 180A near the first notch C1 may be complementary to a shape of the first notch C1, and a shape of a side of the conductive element 180A near the second notch C2 may be complementary to a shape of the second notch C2.

It is worth mentioning that a distance between the first contact surface TS1 and the second contact surface TS2 may vary along a thickness direction of the insulating structure 130 (such as the direction Y). For example, the first contact surface TS1 and the second contact surface TS2 have a distance d1 at a side adjoining the first electrode 121 or the second electrode 122, and gradually increase to a distance d2 toward a side away from the first electrode 121 or the second electrode 122. In some embodiments, a relationship between the distance d1 and the distance d2 may be 1.5d1≤d2≤3d1. Here, a width of the first sub-chip 100A or a width of the second sub-chip 100B (such as a maximum width of the first semiconductor layer 101 in the direction X) is greater than the distance d2 of the insulating structure 130, such as up to 10 times the distance d2, to ensure that the insulating structure 130 may provide sufficient structural strength. In some implementations, the distance d1 may be 1.5 micrometers, and the distance d2 may be 2.8 micrometers. In addition, the insulating structure 130 may have a concave surface toward a negative Y direction on a side adjoining the upper surface 101S, which may further enhance the light extraction effect of the micro light emitting chip 1A.

In addition, the protection unit 160 may be an insulation layer composed of insulating materials. For example, a material of the protection unit 160 may include inorganic substances such as silicon oxide (SiₓO_{y}) or titanium dioxide (TiO₂), or a coating layer composed of a single material, but is not limited thereto. In detail, in the embodiment, the protection unit 160 is configured on an outer surface of the first sub-chip 100A, the second sub-chip 100B and the insulating structure 130, and has a first surface 161 and a second surface 162 opposite to each other in the direction Y, with the first sub-chip 100A, the second sub-chip 100B and the insulating structure 130 located between the first surface 161 and the second surface 162. The first surface 161 and the second surface 162 of the protection unit 160 may partially or completely cover the outer surface or the upper surface 101S of the first sub-chip 100A, the second sub-chip 100B and the insulating structure 130. Moreover, in addition to the first surface 161 and the second surface 162, the protection unit 160 may also extend to cover a sidewall of the micro light emitting chip 1A (that is, a peripheral side surface in the X direction). In other words, the first sub-chip 100A, the second sub-chip 100B, the insulating structure 130, and the conductive element 180A may all be integrated in the protection unit 160. In this way, the protection unit 160 may not only prevent moisture, oxygen, or other impurities from invading the first sub-chip 100A and the second sub-chip 100B, but also further strengthen the structural strength of the micro light emitting chip 1A, enhancing the device reliability of the micro light emitting chip 1A.

In some embodiments, the protection unit 160 may be integrally formed with the insulating structure 130 and made of a same material. That is to say, the insulating structure 130 may also be further flush with the first surface 161 of the protection unit 160. Additionally, since the protection unit 160 and the insulating structure 130 become a single structure, especially in an embodiment where the insulating structure 130 is not a portion of the micro light emitting chip 1A, the protection unit 160 may have a supporting function as a beam structure on a side of the first surface 161. Specifically, without affecting the light emission performance of the upper surface 101S, appropriately increasing the thickness of the protection unit 160 on the first surface 161 (such as 1.5 to 3 micrometers) may directly provide support for the first sub-chip 100A and the second sub-chip 100B in the Y direction. By means of this, during the chip transfer process, the protection unit 160 may generate an effect similar to a temporary substrate, giving the entire micro light emitting chip 1A sufficient mechanical strength. In some embodiments, the protection unit 160 and the insulating structure 130 may be manufactured in a same process. However, the disclosure is not limited thereto. In some embodiments, the protection unit 160 and the insulating structure 130 may be made of different materials.

In addition, in the embodiment, the first sub-chip 100A and the second sub-chip 100B may each further include a first contact layer 111 and a second contact layer 112. The first contact layer 111 is disposed between the first semiconductor layer 101 and the first electrode 121. The second contact layer 112 is disposed on the second semiconductor layer 102. The first contact layer 111 and the second contact layer 112 may, for example, be highly doped N-type or P-type semiconductor material layers, or other appropriate materials to facilitate ohmic contact between each of the conductive element 180A, the first electrode 121, the second electrode 122, the first semiconductor layer 101 and the second semiconductor layer 102. However, the disclosure is not limited thereto. In some embodiments, the first sub-chip 100A and the second sub-chip 100B may also be configured without the first contact layer 111 and the second contact layer 112.

On the other hand, the micro light emitting chip 1A may also include a Bragg reflection layer 140. The Bragg reflection layer 140 may extend in the direction X and cover a same side of the first sub-chip 100A and the second sub-chip 100B at the same time. In the direction Y, the Bragg reflection layer 140 is disposed between the first sub-chip 100A and the first electrode 121, and disposed between the second sub-chip 100B and the second electrode 122. The Bragg reflection layer 140 may have the functions of insulation and reflecting beams. The foregoing conductive element 180A may, by passing through a via TH12 and a via TH21 in the Bragg reflection layer 140, be respectively electrically connected to the second semiconductor layer 102 of the first sub-chip 100A and the first semiconductor layer 101 of the second sub-chip 100B. The conductive element 180A may be configured between the Bragg reflection layer 140 formed of inorganic material and the protection unit 160 to avoid breakage.

On the other hand, in the embodiment, the micro light emitting chip 1A may further include a transparent conductive layer 170. The transparent conductive layer 170 may serve as a current diffusion layer, covering the second contact layer 112 of the first sub-chip 100A and disposed between the second semiconductor layer 102 and the conductive element 180A. The transparent conductive layer 170 may also cover the second contact layer 112 of the second sub-chip 100B, and be disposed between the second semiconductor layer 102 and the second electrode 122. The transparent conductive layer 170 may include transparent conductive materials, such as indium tin oxide (ITO), indium zinc oxide (IZO), aluminum zinc oxide (AZO), cadmium tin oxide, tin oxide (SnO₂), zinc oxide (ZnO), or any other transparent conductive material, but is not limited thereto.

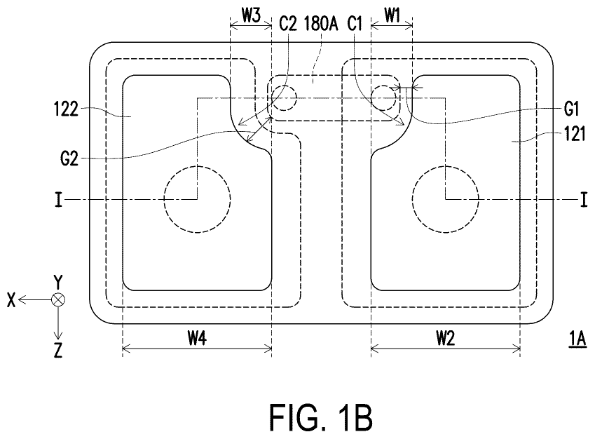

FIG. 2 is a schematic cross-sectional view of a micro light emitting chip according to an embodiment of the disclosure. Referring to FIG. 2, a micro light emitting chip 1B of the embodiment is similar to the micro light emitting chip 1A. The main difference is that: a quantity of sub-chips serially connected is different. In detail, the micro light emitting chip 1B further includes a third sub-chip 100C and a conductive element 180B, and the protection unit 160 further covers the third sub-chip 100C and the conductive element 180B. Between the second sub-chip 100B and the third sub-chip 100C, there may also be the insulating structure 130, respectively having the first contact surface TS1 and the second contact surface TS2 with the second sub-chip 100B and the third sub-chip 100C. The conductive element 180B is electrically connected to the second sub-chip 100B and the third sub-chip 100C. That is to say, the micro light emitting chip 1B is formed by 3 sub-chips serially connected with each other. Furthermore, the second electrode 122 is connected to the transparent conductive layer 170, and then through a via TH32 penetrating through the protection unit 160 and the Bragg reflection layer 140, is instead electrically connected to the second semiconductor layer 102 of the third sub-chip 100C.

In other embodiments, the quantity of sub-chips may be more than 3 (such as 4 or 5), and a quantity of conductive elements, and a quantity of the insulating structures 130 between two adjacent sub-chips may increase correspondingly. For example, when the quantity of sub-chips is n, the quantity of conductive elements and the insulating structures 130 may be n−1, and the disclosure is not limited thereto.

In the embodiment, the first electrode 121 of the micro light emitting chip 1B may also have the first notch C1 as shown in FIG. 1B, and the second electrode 122 of the micro light emitting chip 1B may also have the second notch C2 as shown in FIG. 1B. The conductive element 180A may have a portion located in the first notch C1, and the conductive element 180B may have a portion located in the second notch C2.

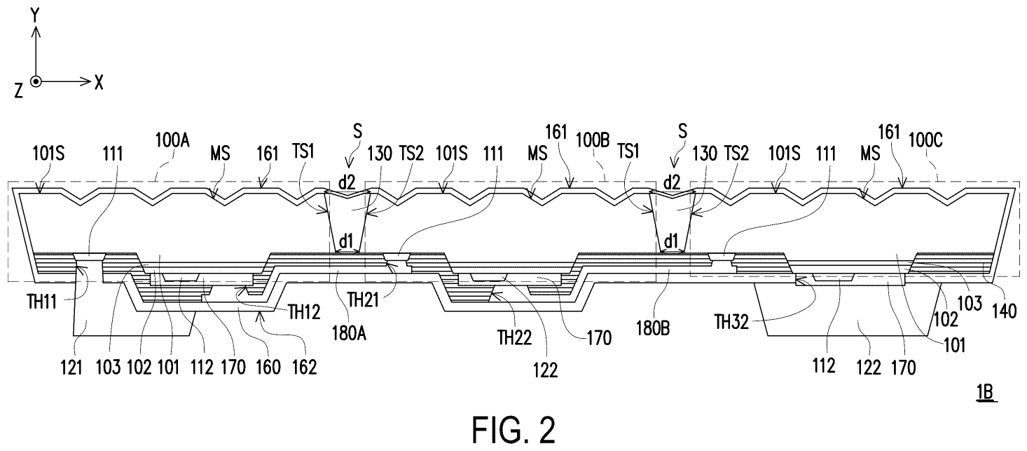

FIG. 3 is a schematic cross-sectional view of a micro light emitting chip structure according to an embodiment of the disclosure. In FIG. 3, a micro light emitting chip structure 10A is shown loading two micro light emitting chips 1H as an exemplary description. On the other hand, the first electrode 121 (or the second electrode 122) and the insulating structure 130 are respectively located at opposite sides of the micro light emitting chip 1H, or respectively located at opposite sides of the first sub-chip 100A (or the second sub-chip 100B). In addition, the first electrode 121 and the second electrode 122 are located between the micro light emitting chip 1H and a temporary substrate 11. A fixing element 12 (such as an electrically insulating adhesive) fixes the multiple micro light emitting chips 1H to the temporary substrate 11 through the fixing element 12. The multiple micro light emitting chips 1H are electrically insulated from the temporary substrate 11. The temporary substrate 11, for example, is a temporary substrate such as a plastic substrate, a glass substrate, or a sapphire substrate, which may have stability and a flat surface, but is not limited thereto. In the embodiment, the micro light emitting chip 1H further includes an optical structure 150 disposed at one side of the micro light emitting chip 1H, for example, directly covering the upper surface 101S and covering a microstructure MS, but in another embodiment not illustrated, the optical structure 150 may not be disposed.

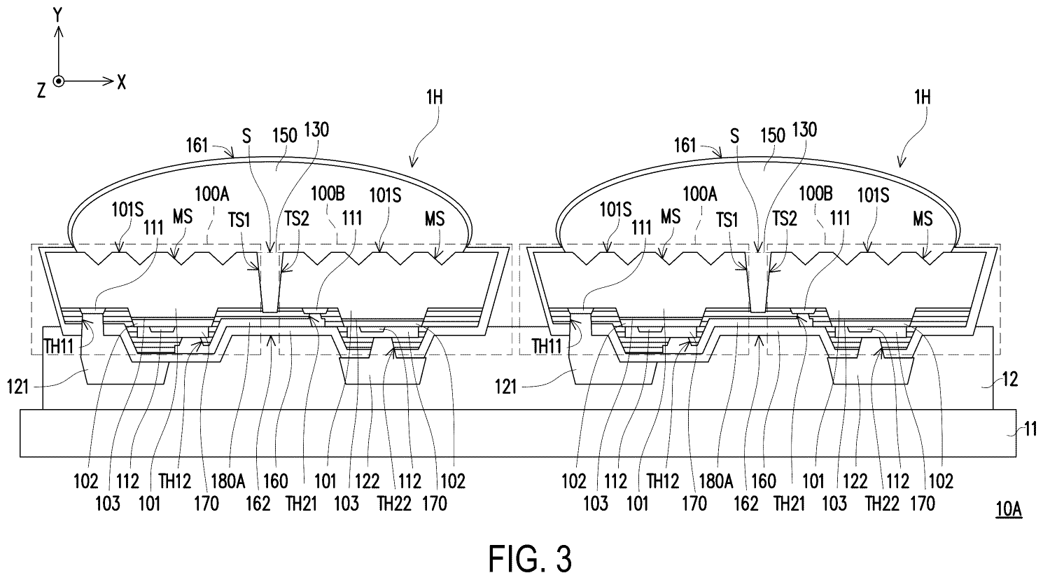

FIG. 4 is a schematic cross-sectional view of a display panel according to an embodiment of the disclosure. Referring to FIG. 4, a display panel 20A includes a circuit substrate 21. The circuit substrate 21 has multiple pixel circuits 22 and bonding pads 23 that are electrically connected to the pixel circuits 22. The multiple micro light emitting chips 1H are disposed on the circuit substrate 21, and are respectively electrically connected to the bonding pads 23 through the first electrode 121 and the second electrode 122 to complete the electrical connection between the multiple micro light emitting chips 1H and the circuit substrate 21. After the micro light emitting chips 1H in FIG. 3 are manufactured, a mass transfer technology may be utilized to simultaneously pick up the multiple micro light emitting chips 1H and transfer onto the circuit substrate 21 to complete the display panel 20A.

In the embodiment, the circuit substrate 21 includes various signal lines (such as data lines, scan lines, or power lines, which are not illustrated) and the pixel circuits 22 connected thereto, which may respectively provide electrical signals to the two bonding pads 23 in order to allow the micro light emitting chips 1H to emit display beams. It is worth mentioning that the three micro light emitting chips 1H shown in FIG. 4 may emit beams of different wavelength ranges. For example, the three micro light emitting chips 1H may respectively emit a beam L1 of red light wavelength, emit a beam L2 of green light wavelength, and emit a beam L3 of blue light wavelength, and of course the disclosure is not limited thereto. In other embodiments, the beams emitted by the multiple micro light emitting chips 1H may also have substantially a same wavelength range.

The circuit substrate 21, for example, utilizes silicon wafer material and includes a complementary metal oxide semiconductor (CMOS) driving substrate in order to improve the reaction speed of various switching elements in the circuit substrate 21 and reduce power consumption to meet the needs of fast response and high resolution of the display panel 20A. However, the disclosure is not limited thereto. In other embodiments, the circuit substrate 21 may also be a printed circuit substrate (PCB) or a combination of a glass substrate and a pixel circuit layer. The pixel circuit layer is formed on the glass substrate utilizing a semiconductor process. The pixel circuit layer may include active elements (such as thin film transistors) and multiple signal lines (such as data lines, scan lines, or power lines, which are not illustrated), but is not limited thereto.

By means of the above, the display panel 20A utilizing the micro light emitting chips 1H as display pixels can have advantages such as high brightness, low power consumption, and good structural strength, which can reduce the probability of pixel defects, enhance the bonding yield rate of the transfer process, and further enhance product competitiveness.

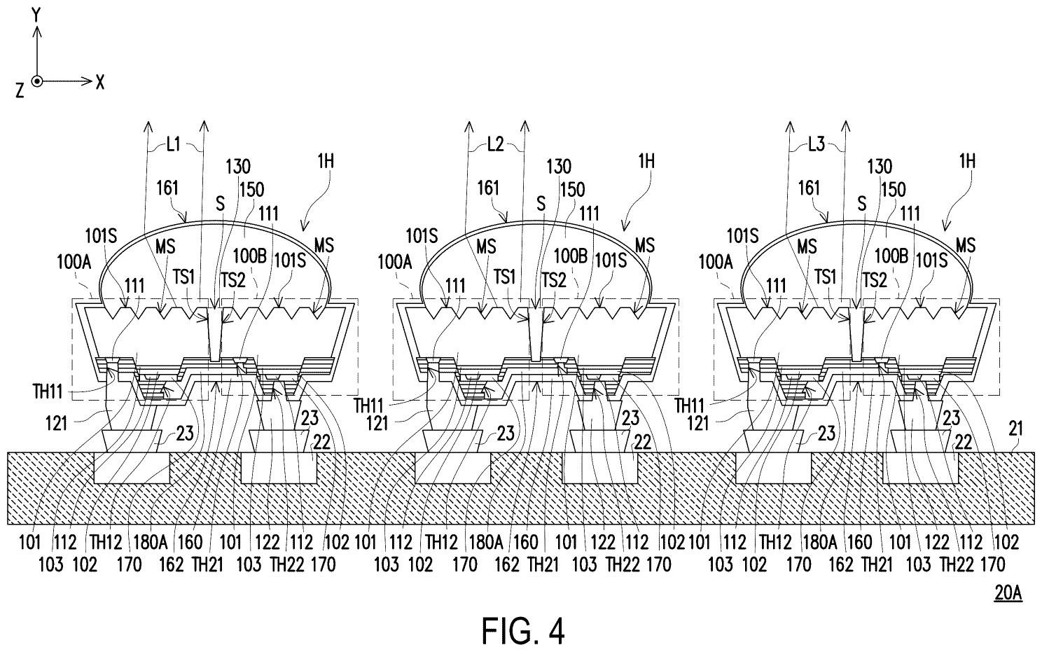

FIG. 5 is a schematic bottom view of a micro light emitting chip according to another embodiment of the disclosure. Referring to FIG. 5, a micro light emitting chip 1J of the embodiment is similar to the micro light emitting chip 1A in FIG. 1B. The main difference between the two is described below. In the micro light emitting chip 1J of the embodiment, the first notch C1 and the second notch C2 are away from each other. In an embodiment, an outer profile of the first electrode 121 and an outer profile of the second electrode 122 are in 180-degree rotational symmetry. In this way, compared with FIG. 1B, a center of gravity of the micro light emitting chip 1J of the embodiment is closer to a geometric center of the micro light emitting chip 1J, which may effectively prevent the micro light emitting chip 1J from tilting during mass transfer. In the embodiment, an orthogonal projection area of a conductive element 180J on the reference plane P1 (as shown in FIG. 1A) is greater than or equal to the orthogonal projection area of the insulating structure 130 (as shown in FIG. 1A) on the reference plane P1. This may further enhance the supporting effect of the conductive element 180J to overcome a problem of weaker structural strength in a middle region of the micro light emitting chip 1J where the conductive element 180J is located being supported by the insulating structure 130. The design of larger area of the conductive element 180J also facilitates a reduction of current crowding effect. In an embodiment, a ratio of the orthogonal projection area of the insulating structure 130 on the reference plane P1 to the orthogonal projection area of the conductive element 180J on the reference plane P1 is greater than 0.2 and less than 1. In addition, in an embodiment, a ratio of the width W1 of the first notch C1 to the width W2 of the first electrode 121 is greater than or equal to 0.2 and less than or equal to 0.5, and a ratio of the width W3 of the second notch C2 to the width W4 of the second electrode 122 is greater than or equal to 0.2 and less than or equal to 0.5.

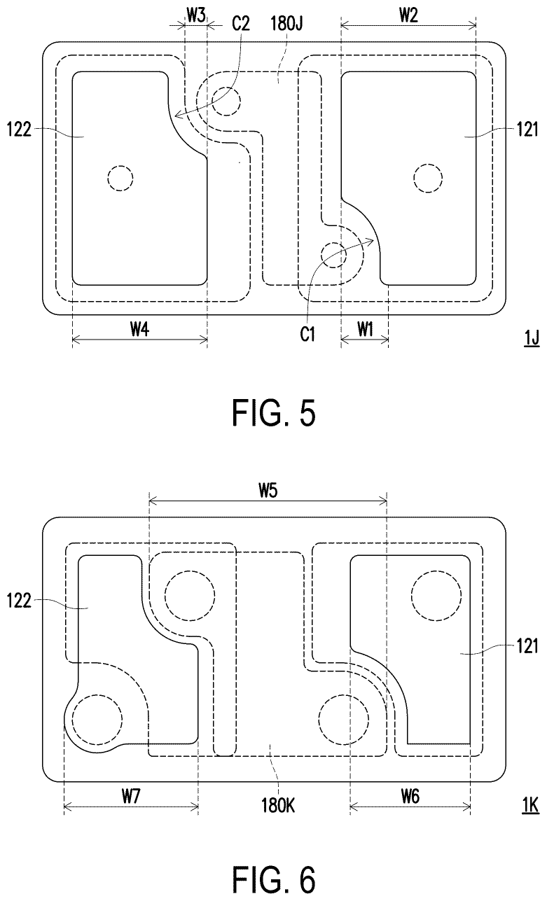

FIG. 6 is a schematic bottom view of a micro light emitting chip according to yet another embodiment of the disclosure. Referring to FIG. 6, a micro light emitting chip 1K of the embodiment is similar to the micro light emitting chip 1J in FIG. 5. The main difference between the two is that, in the micro light emitting chip 1K of the embodiment, a maximum width W5 of a conductive element 180K is greater than or equal to a maximum width W6 of the first electrode 121, or greater than or equal to a maximum width W7 of the second electrode 122. In addition, in the embodiment, an orthogonal projection area of the conductive element 180K on the reference plane P1 (as shown in FIG. 1A) is greater than an orthogonal projection area of the first electrode 121 on the reference plane P1, or greater than an orthogonal projection area of the second electrode 122 on the reference plane P1. This is because the middle region of the micro light emitting chip 1J where the conductive element 180J is located is supported by the insulting structure 130 (as shown in FIG. 1A) and has the problem of weaker structural strength, and designing the conductive element 180K with a larger area can provide better support to overcome this problem. In an embodiment, a ratio of the orthogonal projection area of the conductive element 180K on the reference plane P1 to the orthogonal projection area of the first electrode 121 on the reference plane P1 is greater than 1 and less than or equal to 1.5, and a ratio of the orthogonal projection area of the conductive element 180K on the reference plane P1 to the orthogonal projection area of the second electrode 122 on the reference plane P1 is greater than 1 and less than or equal to 1.5.

In summary, in the micro light emitting chip, the micro light emitting chip structure, and the display panel of the embodiment of the disclosure, the first electrode and the second electrode respectively have the first notch and the second notch. The conductive element is configured between the first notch of the first electrode and the second notch of the second electrode. The sum of the orthogonal projection areas of the first electrode, the second electrode and the conductive element on the reference plane parallel to the two sub-chips is greater than or equal to 0.6 times the orthogonal projection area of the micro light emitting chip on the reference plane. Alternatively, the first notch and the second notch are away from each other, and the outer profile of the first electrode and the outer profile of the second electrode are in 180-degree rotational symmetry. Therefore, the conductive element may have a larger area, which can support the structural strength of the connected sub-chips to effectively reduce breakage or tilting of the micro light emitting chip at a connection point of the sub-chips due to uneven force during the mass transfer process. Thus, the micro light emitting chip of the embodiment of the disclosure can have better structural strength, and the micro light emitting chip structure and the display panel of the embodiment of the disclosure can have better structural strength and manufacturing yield rate.

What is claimed is:

1. A micro light emitting chip, comprising:
two sub-chips;
an insulating structure, disposed between the two sub-chips to allow the two sub-chips to be electrically insulated from each other at the insulating structure;
a first electrode and a second electrode, respectively connected to the two sub-chips, and respectively having a first notch and a second notch; and
a conductive element, configured between the first notch of the first electrode and the second notch of the second electrode, and electrically connected to the two sub-chips,
wherein, a sum of orthogonal projection areas of the first electrode, the second electrode and the conductive element on a reference plane parallel to the two sub-chips is greater than or equal to 0.6 times an orthogonal projection area of the micro light emitting chip on the reference plane.

2. The micro light emitting chip according to claim 1, wherein the orthogonal projection area of the conductive element on the reference plane is greater than or equal to 0.1 times the orthogonal projection area of the micro light emitting chip on the reference plane, and less than or equal to 0.5 times the orthogonal projection area of the micro light emitting chip on the reference plane.

3. The micro light emitting chip according to claim 1, wherein the orthogonal projection area of the conductive element on the reference plane is greater than or equal to the orthogonal projection area of the first electrode on the reference plane, or greater than or equal to the orthogonal projection area of the second electrode on the reference plane.

4. The micro light emitting chip according to claim 1, wherein a height of the conductive element in a direction perpendicular to the reference plane is less than a height of the micro light emitting chip in the direction perpendicular to the reference plane.

5. The micro light emitting chip according to claim 1, wherein the orthogonal projection of the conductive element on the reference plane is away from the orthogonal projection of the first electrode on the reference plane, and away from the orthogonal projection of the second electrode on the reference plane.

6. The micro light emitting chip according to claim 1, wherein a ratio of a maximum width of the first notch to a maximum width of the first electrode in a same direction is greater than or equal to 0.2 and less than or equal to 0.5, and a ratio of a maximum width of the second notch to a maximum width of the second electrode in a same direction is greater than or equal to 0.2 and less than or equal to 0.5.

7. The micro light emitting chip according to claim 1, wherein the first notch and the second notch are opposite to each other.

8. The micro light emitting chip according to claim 1, wherein the first notch and the second notch are away from each other.

9. The micro light emitting chip according to claim 8, wherein the orthogonal projection area of the conductive element on the reference plane is greater than or equal to an orthogonal projection area of the insulating structure on the reference plane.

10. The micro light emitting chip according to claim 8, wherein a maximum width of the conductive element is greater than or equal to a maximum width of the first electrode, or greater than or equal to a maximum width of the second electrode.

11. A micro light emitting chip structure, comprising:
a temporary substrate;
a fixing element; and
a plurality of micro light emitting chips, fixed on the temporary substrate through the fixing element, wherein the micro light emitting chips are electrically insulated from the temporary substrate, and each of the micro light emitting chips comprises:
two sub-chips;
an insulating structure, disposed between the two sub-chips to allow the two sub-chips to be electrically insulated from each other at the insulating structure;
a first electrode and a second electrode, respectively connected to the two sub-chips, and respectively having a first notch and a second notch; and
a conductive element, configured between the first notch of the first electrode and the second notch of the second electrode, and electrically connected to the two sub-chips,
wherein, a sum of orthogonal projection areas of the first electrode, the second electrode and the conductive element on a reference plane parallel to the two sub-chips is greater than or equal to 0.6 times an orthogonal projection area of the micro light emitting chip on the reference plane.

12. A display panel, comprising:
a circuit substrate, provided with a plurality of pixel circuits; and
a plurality of micro light emitting chips, disposed on the circuit substrate, each of the micro light emitting chips comprising:
two sub-chips;
an insulating structure, disposed between the two sub-chips to allow the two sub-chips to be electrically insulated from each other at the insulating structure;
a first electrode and a second electrode, respectively connected to the two sub-chips, and respectively having a first notch and a second notch, wherein one of the first electrode and the second electrode is electrically bonded to one of the pixel circuits; and
a conductive element, configured between the first notch of the first electrode and the second notch of the second electrode, and electrically connected to the two sub-chips,
wherein, a sum of orthogonal projection areas of the first electrode, the second electrode and the conductive element on a reference plane parallel to the two sub-chips is greater than or equal to 0.6 times an orthogonal projection area of the micro light emitting chip on the reference plane.

13. The display panel according to claim 12, wherein the orthogonal projection of the conductive element on the reference plane is away from the orthogonal projection of the first electrode on the reference plane, and away from the orthogonal projection of the second electrode on the reference plane.

14. A micro light emitting chip, comprising:
two sub-chips;
an insulating structure, disposed between the two sub-chips to allow the two sub-chips to be electrically insulated from each other at the insulating structure;
a first electrode and a second electrode, respectively connected to the two sub-chips, and respectively having a first notch and a second notch; and
a conductive element, configured between the first notch of the first electrode and the second notch of the second electrode, and electrically connected to the two sub-chips,
wherein, the first notch and the second notch are away from each other, and an outer profile of the first electrode and an outer profile of the second electrode are in 180-degree rotational symmetry.
